(19) United States
(12) Patent Application Publication
(10) Pub. No.: US 2012/0032337 A1
(43) Pub. Date: Feb. 9, 2012

(54) Flip Chip Substrate Package Assembly and Process for Making Same

(75) Inventors: Chen-Fa Lu, Gangshan Township (TW); Chen-Hua Yu, Hsin-Chu (TW); Chung-Shi Liu, Shin-Chu (TW)

(73) Assignee: Taiwan Semiconductor Manufacturing Company, Ltd., Hsin-Chu (TW)

(21) Appl. No.: 12/852,196

(22) Filed: Aug. 6, 2010

(51) Int. Cl. H01L 23/498; H01L 21/50; H05K 1/18

(52) U.S. Cl. 257/773; 174/261; 438/126; 257/E21.499; 257/E23.06

(57) ABSTRACT

Apparatus and methods for providing a package substrate and assembly for a flip chip integrated circuit. A substrate is provided having a solder mask layer, openings in the solder mask layer for conductive bump pads, and openings in the solder mask layer between the conductive bump pads exposing a dielectric layer underneath the solder mask layer. A flip chip integrated circuit is attached to the substrate using a thermal reflow to reflow conductive solder bumps on the integrated circuit to the conductive bump pads. An underfill material is dispensed beneath the integrated circuit and physically contacting the dielectric layer of the substrate. In additional embodiments, one or more integrated circuits are flip chip mounted to the substrate. The resulting assembly has improved thermal characteristics over the assemblies of the prior art.

### BACKGROUND

A current common requirement for an advanced electronic circuit and particularly for circuits manufactured as integrated circuits (“ICs”) in semiconductor processes is the use of a substrate or interposer to mount a “flip chip” integrated circuit having bumps on the terminals or connections for the integrated circuit. In a flip chip package, the bumps of solder including lead or lead free solder compositions, are mounted with the integrated circuit oriented face down on the substrate, and a thermal reflow process is used to complete the solder connections. These integrated circuit devices may have tens or hundreds of input and output terminals for receiving and sending signals and/or for coupling to power supply connections.

In a flip chip package application, the IC is mounted face down (flipped) with respect to the substrate. An integrated circuit is mounted face down to a package substrate. The substrate has a core with plated through-hole connections extending from the die side to the circuit board side. The substrate includes a dielectric layer and multiple level metal connections on both the upper and lower side. The dielectric layer may be formed of insulating materials including polyimides, organics, inorganics, resins, epoxies and the like.

Conductive bump pads disposed on the die side of the substrate are referred to as “bump pads”. These bump pads are coupled electrically to quantities of pre-solder material that lies over the conductive bump pads. Pre-solder is disposed in openings formed in the solder mask; these areas are called solder resist openings (“SROs”). Connections are made from the multiple level metal patterns on the die side of the substrate through the core and to the circuit board side of the substrate. These connections may be formed, for example, using a plated through-hole filled with a conductive plug. The metallization layers of the substrate may be formed using copper plating techniques, a seed layer may be electroless plated over a layer of the additive build up film or another dielectric.

A flip chip integrated circuit may be mounted face down by aligning solder bumps or columns on the integrated circuit with corresponding bump pads, so that the solder and the pre-solder material are in contact. A chip attach process is performed using a thermal reflow, the solder and pre-solder materials melt and then are allowed to cool, on reflowing they form the electrical and mechanical connections between the integrated circuit chip and the substrate.

Following chip attach, an underfill material is dispensed beneath the integrated circuit. In the prior art, the underfill material is in contact with the face of the integrated circuit, the solder bumps, and the solder mask.

As is known in the art, a thermal mismatch typically occurs between different materials in integrated circuit packages. For example, a mismatch occurs between the integrated circuit, a semiconductor, and the substrate. The materials have different coefficients of thermal expansion (“CTE”) characteristics which result in mechanical stresses when the devices are operated and the material temperature varies. Typically underfill (“UF”) material is dispensed between the integrated circuit and the substrate after the thermal reflow process. This material is selected to provide a mechanical stress relief to prevent thermal stress damage to the devices. The underfill is selected to help protect the die and the solder bumps during thermal stress, to reduce the likelihood of a mechanical failure such as bump cracks and the like.

Nonetheless, thermally induced mechanical stresses still exist in prior art flip chip packaged ICs. Failures such as bump cracking, bridging shorts between adjacent solder bumps, and cracks in the underfill and in the dielectric layers (delamination) are observed. The underfill and the solder mask layer on the surface of the substrate still have substantially different CTE characteristics so that a CTE mismatch still exists, and thermal damage occurs in the prior art packaged devices even when the underfill is used.

### BRIEF DESCRIPTION OF THE FIGURES

For a more complete understanding of the embodiment, and the advantages thereof, reference is now made to the following descriptions taken in conjunction with the accompanying drawings, in which:

FIG. 1 depicts an illustrative embodiment in a cross-sectional view;

FIG. 2 depicts in a cross-sectional view the illustrative embodiment of FIG. 1 used in an integrated circuit assembly embodiment of the disclosure; and

FIG. 3 depicts in a cross-sectional view in an alternative illustrative embodiment substrate assembly having two flip chip integrated circuit dies mounted thereon.

The drawings, schematics and diagrams are illustrative and not intended to be limiting, but are examples of embodiments of the disclosure, are simplified for explanatory purposes, and are not drawn to scale.

### DETAILED DESCRIPTION OF ILLUSTRATIVE EMBODIMENTS

The making and using of the illustrative embodiments are discussed in detail below. It should be appreciated, however, that the illustrative embodiment provides many applicable inventive concepts that can be embodied in a wide variety of specific contexts. The specific embodiments discussed are merely illustrative and do not limit the scope of the disclosure and the appended claims.

Embodiments which are now described in detail provide novel methods and apparatus to reduce the thermal stresses in packaged integrated circuits. Substrates are used to mount solder bumped flip chip integrated circuits. Solder mask openings expose a portion of the substrate dielectric so that underfill material physically contacts the substrate dielectric, improving the thermal performance of the completed package by reducing mechanical stresses during thermal cycling over the package arrangements used previously.

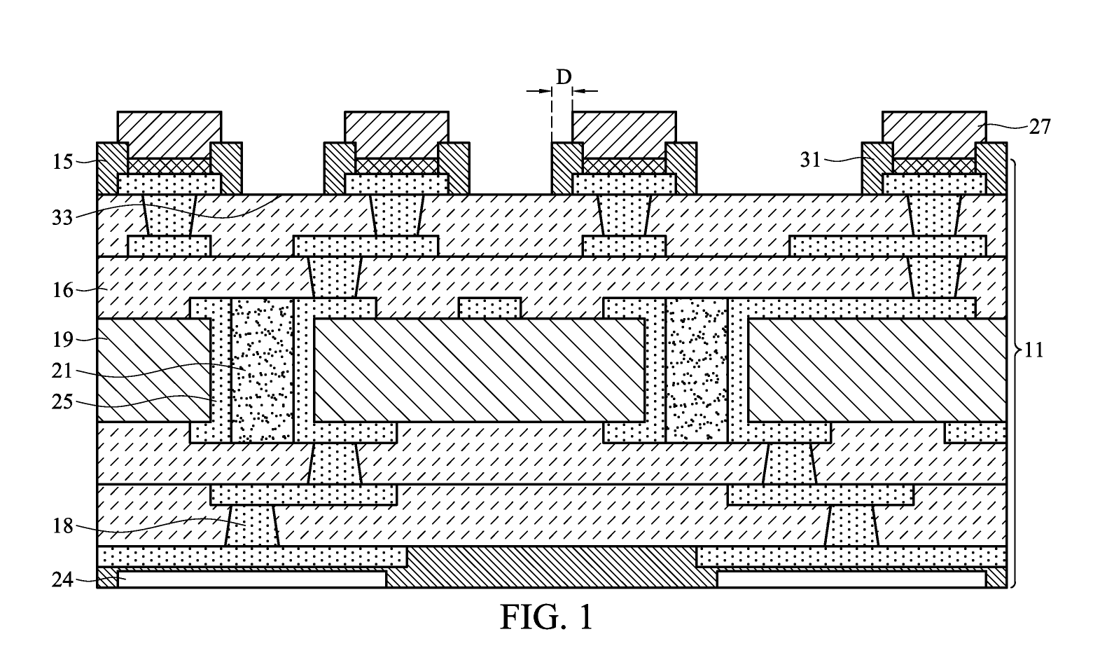

In FIG. 1, an illustrative embodiment is depicted in a cross sectional view. Substrate 11 is provided. The substrate 11 may be formed using a core 19 with through-holes 25 that are plated with a conductor such as copper and its alloys, or with other conductive metals and their alloys. The through-holes 25 are filled with conductive plugs or filler material 21. Dielectric 16, which may be an additive build up film or other insulator, is shown covering both sides of the core 19. Multiple level metallization layers such as 18 form conductive traces in the horizontal and in the vertical directions. Solder mask 15 is shown on both the circuit board side, surrounding ball lands 24, which are configured to receive solder balls for making the external connectors of the packaged integrated circuit, and on the die side (the upper side of substrate 11 in FIG. 1). Bump pads 17 are shown at the upper or chip side surface of the dielectric 16, and these are covered by solder mask layer 15 with solder resist openings (“SROs”) in the solder mask 15 that are filled with pre-solder material 27.

Solder resist openings 33 are formed on the die side of the substrate 11 of FIG. 1. In one illustrative method embodiment, a laser drill process step is performed on solder mask 15 to form solder resist openings 33. In this non-limiting example embodiment, this step may be performed after the pre-solder material 27 is disposed on the bump pads 17. In any event, solder mask 15 is now patterned into solder mask rings (“SMRs”) 31 that are annular rings centered on the bump pads 17, with solder resist openings 33 formed between the bump pads and exposing the upper surface of the dielectric layer 16. The formation of the SMRs 31 may be accomplished using an additional laser drill patterning step after pre-solder material 27 is disposed on the bump pads 17.

Alternative methods that are contemplated as additional embodiments and which fall within the scope of the claims may form the SMRs in FIG. 1 by using the lithographic process step to define the SMRs before the pre-solder is applied to the bump pads. This alternative embodiment process is similar to the one used to form the SRO openings in the solder mask for the pre-solder exposing the bump pads 17. In the alternative embodiments, a process may be performed to define SRO and solder resist openings 33 concurrently by lithography. In this process patterning is done to the solder mask 15 before the pre-solder is applied to the bump pads 17. In this approach, the solder mask resist structure could be formed by lithographic processes, and then the pre-solder material may be printed by stencil printing or otherwise disposed only in the terminal areas. The purpose of forming SMRs 31 or solder mask openings 33 is to allow underfill material disposed underneath an integrated circuit die that may be mounted to the substrate 11 to physically contact the dielectric layer. This novel feature results in reduction in the thermal mechanical stress in the completed package, as will be further described below.

The distance D shown in FIG. 1, the horizontal thickness of the extension of the SMR 31, may vary. In a first embodiment, this distance may be from the outside edge of the copper bump pad 17 to the edge of the SMR 31 and may have a minimum distance of 10 μms. The semiconductor process node, the number of terminals on the integrated circuit, and the diameter of the bump pads 17 will all vary and different distances D for the extension thickness may be selected as appropriate for a particular application. The choice of the distance D may vary; however, a smaller distance D is typically better because when the underfill is dispensed, underfill voids are avoided by using the smaller thickness solder mask rings 31. The embodiments include SMRs with a distance D of greater than or equal to 10 approximately μms. Additional alternative embodiments includes SMRs with a distance D of between 10 and 20 μms, 20 and 30 μms, 30 and 40 μms, 40 and 50 μms, and a distance D greater than 50 μms, as non-limiting examples.

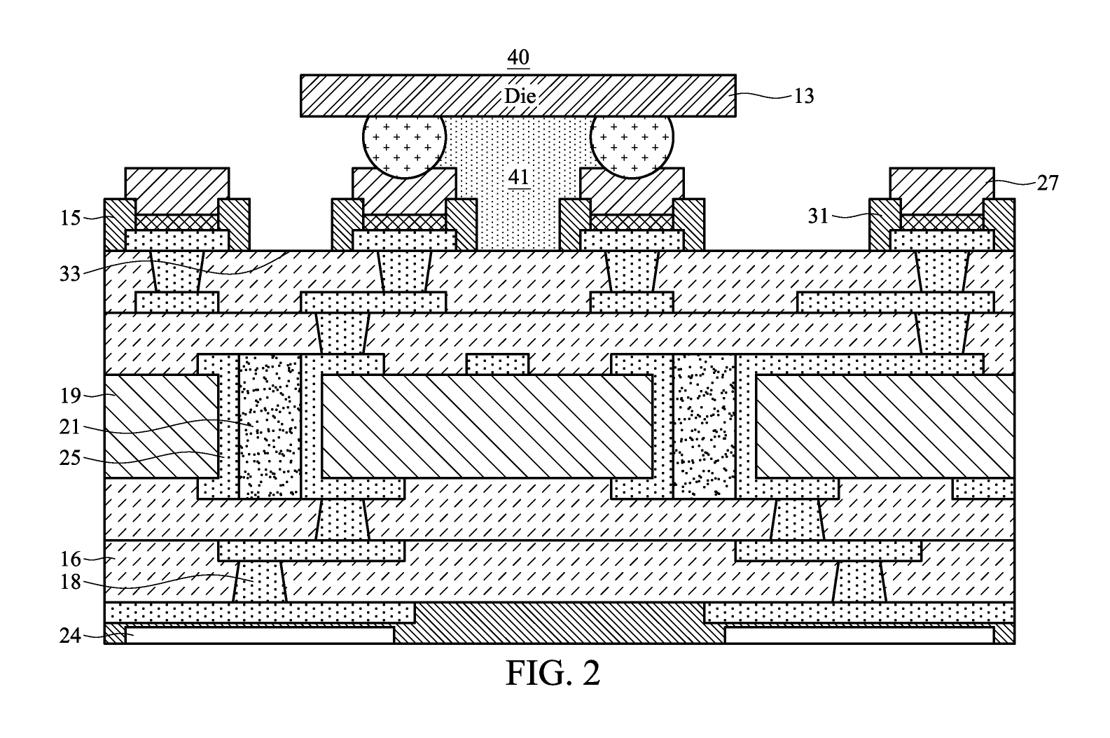

FIG. 2 depicts in another cross-sectional view a completed assembly 40 including the substrate 11 of FIG. 1 following additional process steps to attach a die 13 and provide underfill material 41. Note that as shown in FIG. 2, underfill material 41 lies directly over and physically contacts the upper surface of dielectric layer 16. This arrangement is in sharp contrast to the prior art substrate assemblies, where the underfill material primarily contacts the upper surface of the solder mask. The CTE coefficients of the underfill and the dielectric layer are a better match than the thermal mismatch formed between the underfill material and the solder mask material. The assembly 40 of FIG. 2, an example embodiment, has much better thermal performance and lower mechanical stress due to thermal effects than the arrangements of the prior art.

Any CTE mismatch still present in the illustrative embodiments such as in FIG. 2, is reduced substantially over the prior art arrangements. The reduction of the CTE mismatch and the corresponding reduction in the mechanical stresses the integrated circuit die 13 will experience using the embodiments are significant. As process nodes continue to shrink, and as wafers are now being thinned to enable, for example, the use of through silicon vias (TSVs), additional problems with die warpage have been noticed. The methods and apparatus of the embodiments of this disclosure provide particularly significant advantages for these thin die applications. For semiconductor process nodes at less than 45 nanometers, this improved thermal stress is very important due to the increasingly thinner dies, where die warpage is a bigger concern. The embodiments provide better thermal performance and less pre-solder cracking, underfill cracking, dielectric cracking, ball cracking and bridging shorts than the prior art.

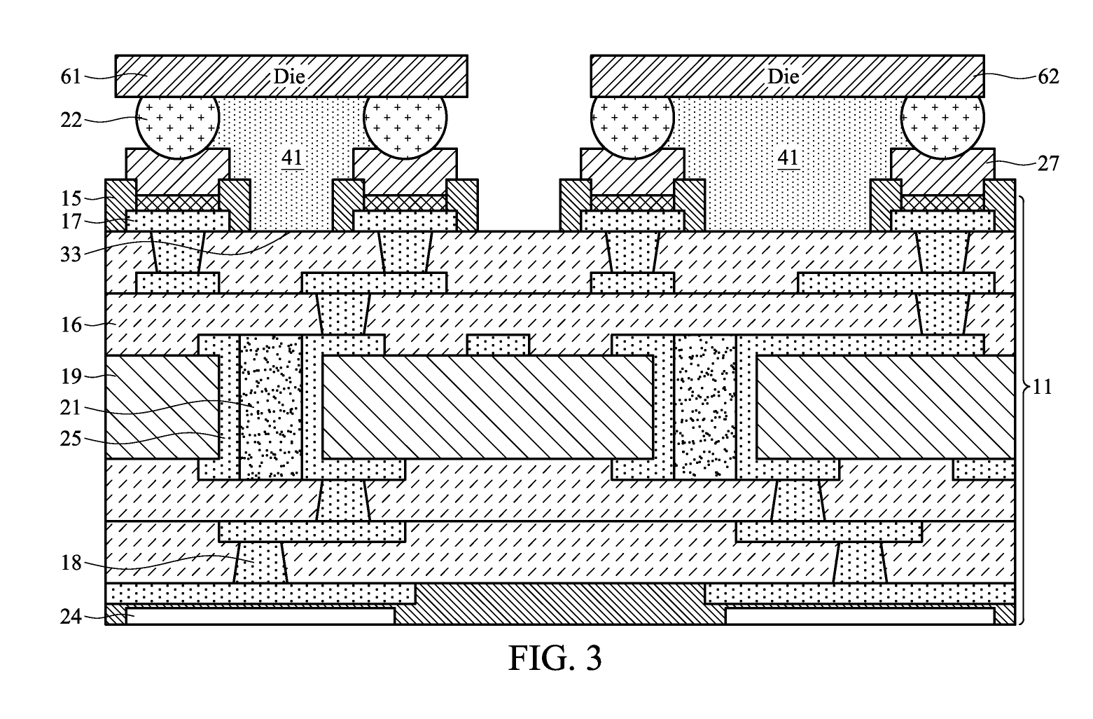

FIG. 3 depicts in an alternative embodiment a multiple die assembly incorporating the solder mask rings of the present disclosure. In FIG. 3, substrate 11 is similar to the substrate of FIG. 1 with the SMR openings 33 in the solder mask 15. In FIG. 3, two dies 61 and 62 are shown mounted to the substrate 11 in flip chip orientation. Underfill 41 is applied beneath each die and the underfill contacts directly the upper surface of dielectric 16 due to the use of the solder mask ring openings 33. Although FIG. 3 depicts two dies mounted to a substrate, more dies could also be mounted to a substrate, if required for a given application, using the embodiments.

In one embodiment, an apparatus comprises a package substrate, a dielectric layer overlying a die side surface of the substrate; a plurality of conductive pads formed at the surface of the dielectric layer; and a solder mask layer disposed over the conductive pads and the dielectric layer; wherein the solder mask layer comprises first openings exposing the conductive pads; and second openings exposing the surface of the dielectric layer between the conductive pads, the second openings spaced from the conductive pads by a minimum distance of 10 microns.

In another embodiment, a method comprises forming a dielectric layer on a die side surface of a package substrate; patterning conductors to form connections to conductive bump pads at the surface of the dielectric layer; covering the dielectric layer and the terminals with a solder mask material; forming solder mask resist openings in the solder mask material corresponding to the terminals; and forming solder mask openings between the conductive bump pads extending through the solder mask material, and exposing the surface of the dielectric layer.

In yet another embodiment, an apparatus comprises a package substrate; a dielectric layer overlying a die side surface of the substrate; a plurality of conductive pads formed at the surface of the dielectric layer; a plurality of integrated circuit dies mounted on the conductive pads; a solder mask layer disposed over the conductive pads and the dielectric layer; underfill material disposed between the integrated circuit dies and the substrate; wherein the solder mask layer comprises first openings exposing the conductive pads; and second openings exposing the surface of the dielectric layer between the conductive pads, the underfill material contacting the surface of the dielectric layer within the second openings, the second openings spaced from the conductive pads by a minimum distance of 10 microns.

Although illustrative example embodiments of the present disclosure and advantages have been described in detail, it should be understood that various changes, substitutions and alterations can be made herein without departing from the spirit and scope of the appended claims. For example, it will be readily understood by those skilled in the art that the methods may be varied while remaining within the scope of the present application and the appended claims.

Moreover, the scope of the present application is not intended to be limited to the particular illustrative embodiments of the methods and steps described in the specification. As one of ordinary skill in the art will readily appreciate from the disclosure, processes, or steps, presently existing or later to be developed, that perform substantially the same function or achieve substantially the same result as the corresponding embodiments described herein may be utilized. Accordingly, the appended claims are intended to include within their scope such processes or steps.

What is claimed is:

1. An apparatus, comprising:
a package substrate comprising:
a dielectric layer overlying a die side surface of the substrate;
a plurality of conductive pads formed at the surface of the dielectric layer; and
a solder mask layer disposed over the conductive pads and the dielectric layer;
wherein the solder mask layer comprises first openings exposing the conductive pads; and second openings exposing the surface of the dielectric layer between the conductive pads, the second openings spaced from the conductive pads by a minimum distance of 10 microns.

2. The apparatus of claim 1, wherein the second openings are spaced from the conductive pads by a minimum distance of 20 microns.

3. The apparatus of claim 1, wherein the second openings are spaced from the conductive pads by a minimum distance of 30 microns.

4. The apparatus of claim 1, wherein the second openings are spaced from the conductive pads by a minimum distance of 40 microns.

5. The apparatus of claim 1, wherein the second openings are spaced from the conductive pads by a minimum distance of 50 microns.

6. A method comprising:
forming a dielectric layer on a die side surface of a package substrate;
patterning conductors to form connections to conductive bump pads at the surface of the dielectric layer;
covering the dielectric layer and the terminals with a solder mask material;
forming solder mask resist openings in the solder mask material corresponding to the terminals; and
forming solder mask openings between the conductive bump pads extending through the solder mask material, and exposing the surface of the dielectric layer.

7. The method of claim 6, further comprising:
mounting a flip chip integrated circuit device with solder bumps on a plurality of the conductive pads;
performing a thermal reflow to electrically and mechanically couple the solder bumps the flip chip to the conductive bump pads; and
dispensing underfill material beneath the flip chip integrated circuit;
wherein the underfill is in physical contact with the die side surface of the dielectric layer.

8. The method of claim 6, wherein the solder mask openings are patterned so that the solder mask forms rings around the conductive bump pads.

9. The method of claim 6, wherein forming the solder mask openings comprises forming solder mask openings that are spaced from the conductive bump pads by a minimum distance of 10 microns.

10. The method of claim 6, wherein forming the solder mask openings comprises performing a lithographic patterning on the solder mask material.

11. The method of claim 10, wherein the lithographic patterning further comprises:
exposing the solder mask material to define the solder mask resist openings and the solder mask openings;
patterning the solder mask material to form the solder mark resist openings and to form the solder mask openings; and
curing the solder mask material.

12. The method of claim 11, further comprising screen printing pre-solder material in the solder mask resist openings.

13. The method of claim 12, further comprising plating solder material onto the pre-solder material.

14. The method of claim 6, wherein forming the solder mask openings comprises forming opening by laser drilling openings on the solder mask material.

15. An apparatus, comprising:
a package substrate comprising:
a dielectric layer overlying a die side surface of the substrate;
a plurality of conductive pads formed at the surface of the dielectric layer;
at least one integrated circuit die mounted on the conductive pads;
a solder mask layer disposed over the conductive pads and the dielectric layer; and
underfill material disposed between the at least one integrated circuit die and the substrate;
wherein the solder mask layer comprises first openings exposing the conductive pads; and second openings exposing the surface of the dielectric layer between the conductive pads, the underfill material contacting the surface of the dielectric layer within the second openings, the second openings spaced from the conductive pads by a minimum distance of 10 microns.

16. The apparatus of claim 15, wherein the second openings are spaced from the conductive pads by a minimum distance of 20 microns.

17. The apparatus of claim 15, wherein the second openings are spaced from the conductive pads by a minimum distance of 30 microns.

18. The apparatus of claim 15, wherein the second openings are spaced from the conductive pads by a minimum distance of 40 microns.

19. The apparatus of claim 15, wherein the second openings are spaced from the conductive pads by a minimum distance of 50 microns.

20. The apparatus of claim 15, further comprising a plurality of integrated circuit dies mounted on respective ones of the conductive pads.
